(19) United States
(12) Patent Application Publication
(10) Pub. No.: US 2010/0301236 A1
(43) Pub. Date: Dec. 2, 2010

(54) Shorten Temperature Recovery Time of Low Temperature Ion Implantation

(76) Inventors: Shih-Yung Shieh, Hsinchu (TW); Cheng-Hui Shen, Hsinchu (TW)

Correspondence Address: STOUT, UXA, BUYAN & MULLINS LLP, 4 VENTURE, SUITE 300, IRVINE, CA, 92618, US

(21) Appl. No.: 12/472,316

(22) Filed: May 26, 2009

(51) Int. Cl. H01J 37/08

(52) U.S. Cl. 250/492.21

(57) ABSTRACT

The present invention discloses a low temperature ion implantation by performing a heating process after the end of an implanting process and before the wafer is moved into the external environment. This invention actively raises wafer temperature at a time no later than implementation of the vacuum venting process, such that the condensed moisture induced by the temperature difference between a vacuum environment inside ion implanter and an external environment outside ion implanter is effectively minimized. The wafer can be heated at a loadlock, a robot for transferring wafer and/or an implantation chamber. The wafer can be heated by a gas, a liquid, a light and/or a heater embedded in a holder for holding the wafer.

### BACKGROUND OF THE INVENTION

1. Field of the Invention

The present invention generally relates to low temperature ion implantation, and more particularly, is focused on shortening the temperature recovery time to reduce or prevent the inducement of moisture condensation from temperature differences.

2. Description of the Prior Art

Low temperature ion implantation is a new branch of ion implantation. It has been discovered that a relatively low wafer temperature during ion implantation is advantageous for formation of shallow junction, especially ultra-shallow junction, which is more and more important for continued miniaturization of semiconductor devices. It also has been proven to be useful for enhancing the yield of ion implantation.

At the beginning of the current low temperature ion implantation, a wafer is moved from an external environment, such as an atmospheric environment, into an implanter, and is cooled to a temperature lower than a temperature of the external environment, such as a temperature lower than the freezing point of water. Herein, the wafer can be cooled, for example, in a cassette outside of the implanter, at a loadlock of the implanter, in an implantation chamber of the implanter, and so on. After the wafer is cooled, an implanting process is performed at the implantation chamber to implant the cooled wafer. Herein, the wafer can be cooled and implanted at the same position or different positions. After that, the implanted and cooled wafer is moved out of the implanter to the external environment for further semiconductor fabrication processing.

However, a serious disadvantage of “condensed moisture” occurs when the temperature of the low temperature ion implantation is lower than room temperature. Typically, this low temperature is below the freeze point of water, such as about −15˜−25° C. or even lower, while the temperature of the external environment usually is room temperature, such as about 15˜25° C. Therefore, if implanted and cooled wafers are directly moved from the chamber to the external environment immediately after the implanting process, the occurrence of “condensed moisture” on the surfaces of the wafers induced by the temperature difference almost is unavoidable. Then, unpredictable damage on micro-structures of the wafers and/or side effects for following semiconductor fabrication processing are almost unavoidable, too.

One conventional solution is to treat the surface of the wafer after the wafer is moved out of the ion implanter and before any following semiconductor fabrication processing, such that the condensed moisture is removed before any following semiconductor fabrication process steps. Clearly, while this conventional solution addresses the damage from condensed moisture by removing it after it is formed, the approach does not prevent the formation of condensed moisture in the first place. Hence, both the cost and occurrence of unpredictable damage on micro-structures of wafers remain high.

Another known solution is to temporarily locate the implanted wafer inside of the ion implanter, such that the wafer is moved out of the ion implanter only after the wafer temperature is naturally raised in a vacuum environment. As usual, a long temperature recovery time is required to allow the wafer temperature to be raised from the temperature of the implanting process to the temperature of the external environment. Clearly, this conventional solution solves the damages of condensed moisture by simply using the vacuum environment to prevent formation of moisture during the period of naturally raising wafer temperature, but, unavoidably, it wastefully requires a long temperature recovery time for the natural raise of wafer temperature inside of the ion implanter at the expense of reduced throughput.

Accordingly, there is a need for a novel and effective approach to improve the “condensed moisture” problem of low temperature ion implantation.

### SUMMARY OF THE INVENTION

The present invention provides a new approach for improving/correcting the condensed moisture problem by actively and effectively eliminating the formation of condensed moisture. Hence, the temperature recovery time is automatically shortened.

One feature of the invention is performing a heating process after the end of the implanting process but before the wafer is moved out from the ion implanter. In other words, the wafer is actively heated in a vacuum environment inside of the ion implanter. Hence, because the wafer temperature is raised before it is moved out from the vacuum environment, condensed moisture on the surface of the wafer can be effectively prevented.

Another feature of the invention is the details of the heating process not being limited. For example, the wafer can be heated in the implantation chamber where the wafer is implanted, at the robot used to transfer the wafer inside of the ion implanter, at the loadlock as an interface between a vacuum environment and an external environment outside of the ion implanter, and so on. The wafer can be heated only at one of the above, and also can be heated at each of the above. In other words, the wafer can be heated only at a specific portion of its movement from the implanted position to the external environment, and also can be heated at each of the positions of its movement from the implanted position to the external environment. For example, the wafer can be heated by gas flowing through the wafer, liquid interacting with the holder for holding the wafer, a heater embedded in a holder for holding the wafer, lights projected on the wafer, and so on. For instance, the wafer temperature can be heated to a room temperature, higher than a dew point of water in the external environment, higher than a freeze point of water, and so on.

A simple example comprises using nitrogen (N2) gas with a large flow rate to heat the wafer and vacuum vent simultaneously. For example, the N2 gas can be dry N2 gas, hot N2 gas, warm N2 gas, N2 gas without vapor, and N2 gas with room temperature. When the N2 temperature and the N2 flow rate are properly adjusted, the wafer can be rapidly heated during the vacuum venting process. Hence, no condensed moisture will be formed.

### BRIEF DESCRIPTION OF THE DRAWINGS

FIG. 1 is a diagram of an ion implanter capable of performing low temperature ion implantation;

FIG. 2A to FIG. 2F show the sectional view in accordance with multiple embodiments of the present invention; and

FIG. 3 shows a flowchart in accordance with an embodiment of the present invention.

### DETAILED DESCRIPTION OF THE INVENTION

A detailed description of the present invention will be discussed in the following embodiments, which are not intended to limit the scope of the present invention and which can be adapted for other applications. While drawings are illustrated in detail, it is appreciated that the quantity of the disclosed components may be greater or less than that disclosed, except for instances expressly restricting the amount of the components.

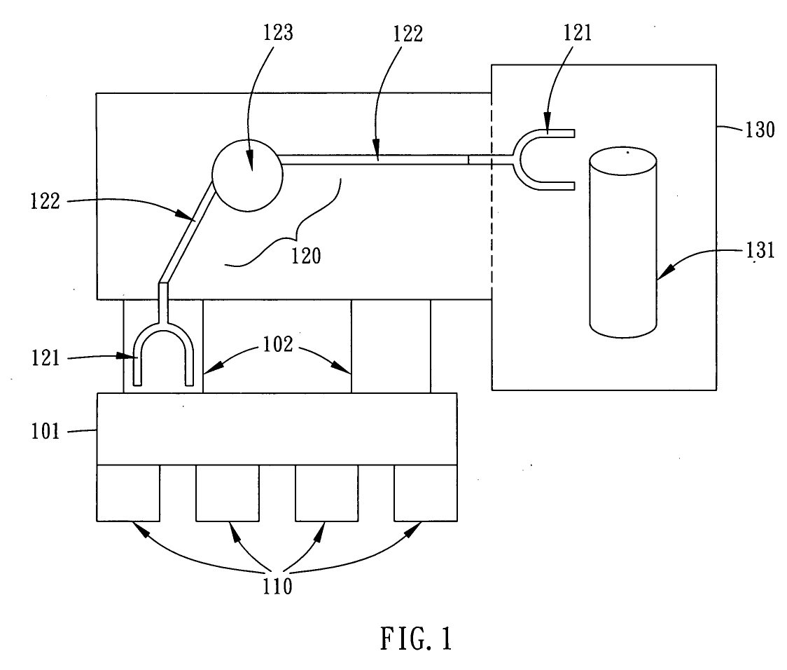

An ion implanter capable of performing low temperature ion implantation for use with the invention is briefly described below and illustrated in FIG. 1. The ion implanter comprises a robot transfer 101, a loadlock 102, a robot 120 and an implantation chamber 130. Many or most of the components may correspond to known elements. Herein, as usual, the robot transfer 101 is used as an interface between the ion implanter and the external environment, which always is in an atmospheric/ambient environment. Also, as usual, the loadlock 102 is used as an interface between a vacuum environment inside of the ion implanter and the robot transfer 101 (or the atmospheric environment), and can be in an atmospheric environment or a vacuum environment. The robot 120 is used to transfer wafers between the loadlock 102 and the implantation chamber 130, which can be located at the loadlock 102, the implantation chamber 130, or an independent robot chamber as shown in FIG. 1, and so on. Indeed, sometimes, there is another robot at the robot transfer 101, but it is omitted to simplify the figures herein. To perform an implanting process in a required low temperature, the implantation chamber 130 usually has a chuck for holding the wafer, a cooling mechanism for cooling the wafer, a motion mechanism for moving wafers to produce a relative motion between the wafer and ion beam, and so on. Herein, owing to these items not being directly related to how the wafer is heated after the wafer is implanted, the details on them are omitted with only a support mechanism 131 being illustrated to indicate the existence of all devices for implanting in a required low temperature context. The ion beam assembly for generating ion beams also is omitted from the figure, because it is not related to how the wafer is heated after the wafer is implanted.

Clearly, to be an interface between the external environment and vacuum environment, the loadlock 102 must allow for a vacuum venting process. In short, as usual, when a wafer is moved from the implantation chamber 130 into the loadlock 102, the loadlock 102 must also be in a vacuum environment. Then, to properly move the wafer into the external environment, the loadlock 102 must be changed to an environment equivalent to the external environment. Hence, a vacuum venting process must be performed to change the environment inside of the loadlock 102. In general, a hot-dry nitrogen gas is applied into the loadlock 102 to raise the pressure inside. Then, a door between the loadlock 102 and the robot transfer 101 is opened after the pressure inside of the loadlock 102 is equal to the pressure inside of the robot transfer 101. Finally, the wafer is moved from the robot interface 101 to the cassette 110 in a process having no simultaneous physical interaction with the operation of the implantation chamber 130.

As is commonly observed, condensed moisture appears on the wafer during and/or just after the vacuum venting process, because the pressure and the temperature of the gas around the wafer are significantly raised when the temperature of the wafer is still almost as low as the temperature of the implanting process.

One embodiment of this invention is based on improving the conventional vacuum venting process at the loadlock 102. The embodiment emphasizes that the wafer surface is closely contacted with the gas during the vacuum venting process. Therefore, the embodiment directly raises the temperature of the gas used for vacuum venting, and optionally increases the flow rate of the gas. Clearly, when the temperature of the gas is high enough, or when the heat carried by the gas is large enough, the wafer temperature can be rapidly increased in a short period. In other words, by adjusting the gas temperature and/or the gas flow rate, the embodiment can rapidly increase the wafer temperature before the wafer is moved into the cassette 110 (or the external environment). Therefore, when the temperature difference between the wafer and the external environment is decreased or even eliminated in a short period, not only is the condensed moisture problem improved or even prevented, but also the throughput is enhanced.

Of course, an ion implanter may have more than one loadlock. In such a situation, to save cost and simplify the construction of the ion implanter, it is possible for only partial ones of the loadlocks 102 to have the heat function with proper isolation value to isolate with other portions of the ion implanter. In such situations, only heat-function enabled loadlocks 102 are used to heat the wafer at a point no later than the time when the when the wafer is moved out of a vacuum environment. For example, an implementation can comprise only the loadlocks that move the wafer out of the vacuum environment being capable of and used to heat the wafer, with other ones of the loadlocks that only move the wafer into the vacuum environment not being capable of and used to heat the wafer.

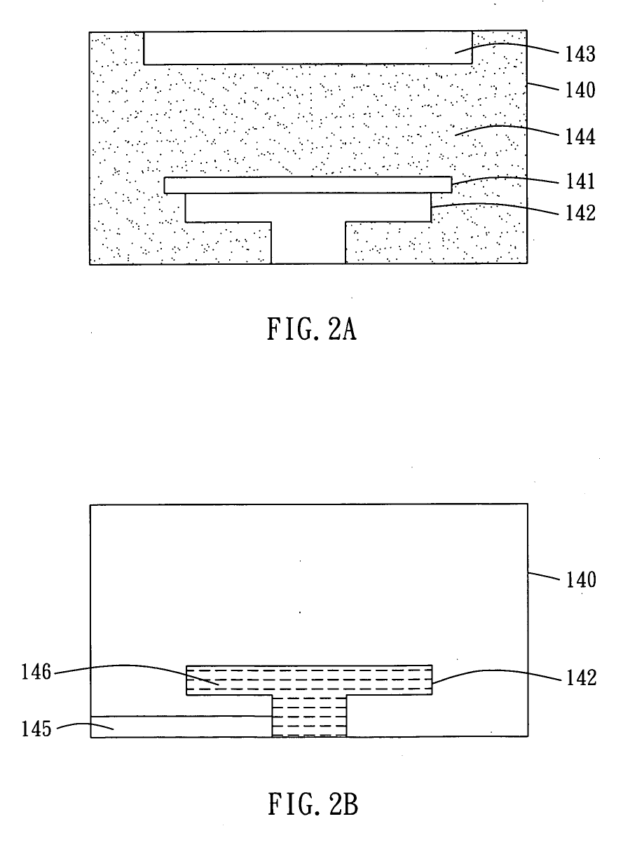

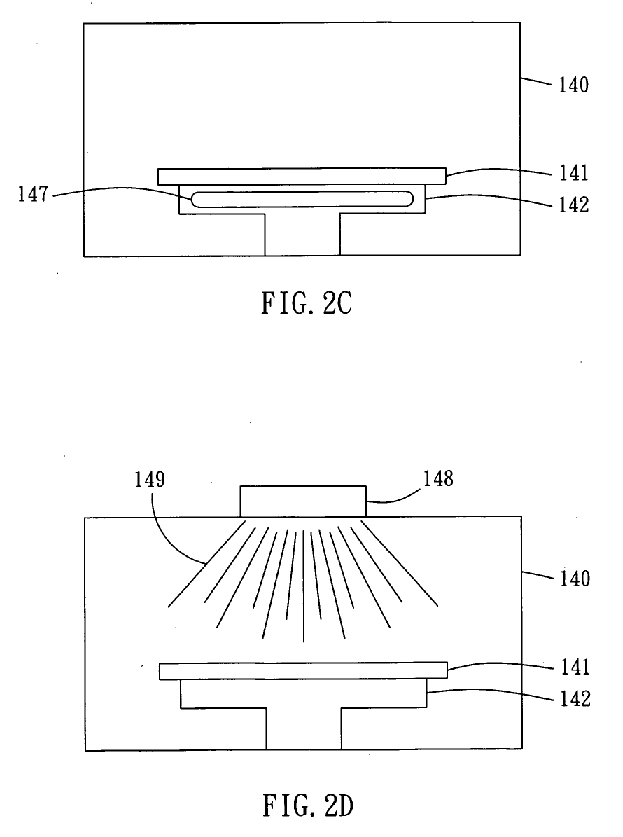

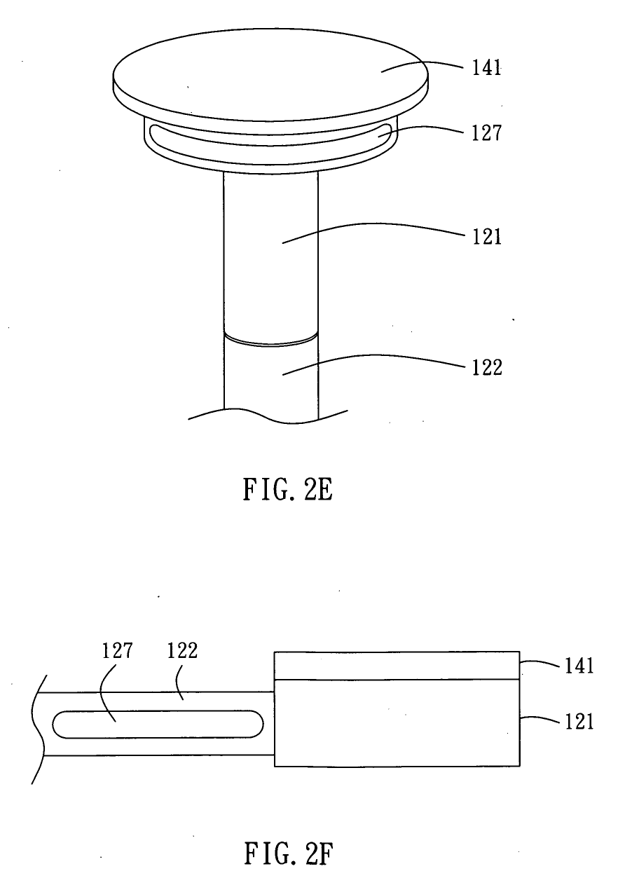

An assembly of hardware for implementing the described embodiment is abbreviated in FIG. 2A. In a chamber 140, such as the chamber of the loadlock 102, a wafer 141 is held by a holder 142 for provision of gas 144 from a gas assembly 143 at a required temperature and/or flow rate. Herein, the gas 144 usually is N2, especially hot-dry N2, but also can be inset gas, gas without vapor or any gas which will not react with the wafer 141. Clearly, when the chamber 140 is filled with the gas 144, the wafer is surrounded (e.g., totally surrounded) by the gas 144 with the temperature of the wafer being commensurately raised. After that, when the wafer is moved out of the chamber 140, the condensed moisture problem is improved, or even prevented.

Significantly, the key is heating the wafer in the chamber 140 before the wafer is moved out, rather than how the wafer is heated within the chamber 140. The previous embodiment can be achieved, for example, by simply modifying conventional hardware already being used for vacuum venting. However, the invention can be achieved by other approaches, as well.

According to another embodiment of the invention, as shown in FIG. 2B, a liquid assembly 145 is used to provide a liquid 146 for heating the wafer. Again, by properly adjusting the temperature, and/or even the flow rate, of the liquid 146, the temperature of the wafer 141 can be suitably (e.g., properly) raised. However, to avoid any reaction between the wafer 141 and the liquid 146 (e.g., liquids at room temperature may react with the wafer and/or comprise water), it may be better for the liquid 146 only to contact the holder 142 and not (e.g., not directly contact) the wafer 141. For example, the liquid 146 can be located only inside of the holder 142 or can flood only the holder 142, such that the liquid 146 directly heats the holder 142 causing the wafer 141 to be indirectly heated. Moreover, to reduce the risk of pollution, the holder 142 optionally can be heated by the liquid 146 before the wafer 141 is moved into the chamber 140, as is the case shown in FIG. 2B.

Another embodiment of the invention is shown in FIG. 2C. Here, a heater 147 is embedded at the holder 142 (such as the hot chuck used to hold the wafer at the loadlock 102 or the support mechanism 131 where the wafer is located at the implantation chamber 130). Available examples of heater 147 can comprise an electric heater and a thermal resistor. The heater 147 can directly heat the holder 142, such that the wafer 141 is indirectly heated. For example, the heater 147 is embedded in a chuck for holding the wafer during an implanting process, such that the wafer can be heated right after the implanting process is completed.

Still another embodiment of the invention is shown in FIG. 2D, comprising a light assembly 148 attached to or within the chamber 140. Available examples of the light assembly 148 can include one or more of lasers and light bulbs. The light assembly 148 can project a light 149 on the wafer 141 to thereby heat the wafer 141. For instance, owing to only light 149 being required, it is possible for the light assembly 148 to be located outside of the chamber 140 with provision of a window for passage of the light 149 therethrough and onto the wafer 141. For example, as a light assembly 148 can be added easily without pipelines, it is possible that one or more light assemblies 148 can be added at or to some chambers and robots of the ion implanter, such that a wafer is heated during the whole movement from the implantation chamber 130 to the cassette 110.

In these embodiments, the wafer 141 can be located on the holder 142 before the wafer 141 (e.g., before the wafer 141 is heated), such that the wafer 141 and the holder 142 are heated together later. Of course, the holder 142 also can be heated before the wafer 141 is located on the holder 142, such that the required period to provide heat for heating wafer 141 is shortened.

In the invention, the particular means and details for heating the wafer are not limited. The above embodiments only provide four possible ways to heat the wafer.

Besides, to reduce or prevent the formation of condensed moisture, the invention only requires that the wafer be heated no later than movement of the wafer into the external environment (such as the atmospheric environment). In short, in this invention, the wafer need not be heated only at the loadlock 102. Indeed, according to one feature of the invention, the wafer can additionally or alternatively be heated at any position of the ion implanter (e.g., the robot and/or the implantation chamber), and can be heated by a gas, a liquid, a light and/or a heater embedded in a holder for holding the wafer, with the only limitation being that the wafer is heated in a vacuum environment.

For example, the wafer can be heated at the implantation chamber 130. Besides the chamber of loadlock 102 being replaced by the implantation chamber 130, all previous embodiments and other equivalent heating ways can be applied to heat the wafer herein.

Similarly, if the robot 120 is located at an independent chamber (e.g., a robot chamber), the above embodiments and other equivalent heating ways also can be applied at the chamber of robot 120. For example, the robot 120 usually has an end effecter for lifting the wafer away from the chuck (or holder) and supporting the wafer when the wafer is transferred from a position (such as loadlock) to another position (such as the implantation chamber), and has both a robot arm 122 and a rotary 123 for transferring the wafer supported by the end effecter 121. Hence, as shown in FIG. 2E and FIG. 2F, a heater 147, such as an electric heater or thermal resistor, can be embedded at the end effecter 121 and/or the robot arm 122, and/or even the rotary 123, to heat and transfer the wafer simultaneously.

Furthermore, the invention only requires heating of the wafer no later than the time of movement thereof to an atmospheric environment (or an external environment) to reduce or prevent condensed moisture. The magnitude and/or technique at which the temperature is raised is not particularly limited by the invention.

For example, the wafer temperature can be raised to room temperature, to the temperature of the external environment, or to the temperature of the cassette. For example, the wafer temperature can be raised to be above the room temperature, above the dew point of the external environment, above the freeze point of the water, or above the temperature inside of the implantation chamber 130. The practical wafer temperature just before it is moved out of the vacuum environment is decided by the whole semiconductor manufacture. Of course, higher wafer temperatures correspond to lower amounts of condensed moisture. However, there are other factors which should be considered, such as the cost of heating the wafer, the throughput of the ion implanter, and the required wafer temperature of the next semiconductor process. Therefore, the invention does not particularly limit a temperature to which the wafer is heated, although three simple and common examples are “equal to the room temperature,” “not lower than the dew point temperature of the external environment” and “a temperature obviously higher than a wafer temperature during the implanting process.”

According to the above discussion, clearly, the invention is not limited to any one or more of (e.g., any of) the below variables: where to heat the wafer inside of the ion implanter, what is used to heat the wafer inside of a vacuum environment, and what temperature the wafer is heated to before the wafer is moved out of the ion implanter.

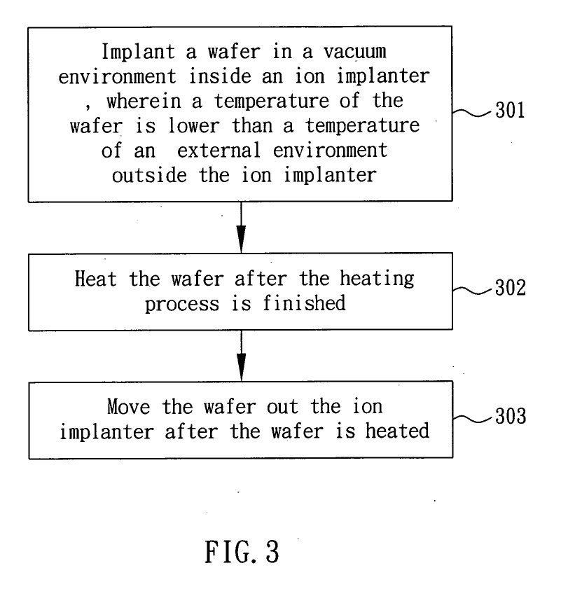

Therefore, another embodiment of the invention is a method for shortening temperature recovery time of low temperature ion implantation. As shown in FIG. 3, the embodiment has at least the following steps. Initially, as shown in block 301, implant a wafer in a vacuum environment inside of an ion implanter, wherein a temperature of the wafer is lower than a temperature of an external environment outside of the ion implanter. Here, how to implant the wafer in such low temperature and how to cool the wafer to the temperature is not limited. Then, as shown in block 302, heat the wafer after the implanting process is finished. Here, the wafer can be heated and implanted at the same portion or different portions of the ion implanter. Finally, as shown in block 303, move the wafer out of the ion implanter after the wafer is heated. Here, a vacuum venting process is performed after the wafer is heated or with the heating process simultaneously.

In comparison with the two common and well-known solutions, the advantages of the invention are very significant.

First, the wafer temperature is raised before the wafer is moved out of the ion implanter. Hence, the formation of condensed moisture is reduced or prevented at/from the source or origin of the condensed moisture. Then, essentially, no extra step is required to remove existing condensed moisture, and micro-structures of wafers will not suffer from unpredictable damage induced by the condensed moisture.

Second, the wafer temperature is raised by actively heating the wafer inside of the ion implanter. Hence, the wafer temperature can be rapidly increased, and then the required temperature recovery time (from the wafer temperature which can be essentially equal to that of the implanting process and/or essentially equal to that of the external environment) is significantly shortened. Then, the throughput of the ion implanter is significantly enhanced.

Third, the invention is very flexible on the details of the heating process and the heating mechanism for heating the wafer. Hence, the invention can be achieved by simply amending the current/commercial ion implanter capable of performing low temperature ion implantation. Therefore, the invention is useful for commercial ion implanters capable of performing low temperature ion implantation.

Although specific embodiments have been illustrated and described, it will be appreciated by those skilled in the art that various modifications may be made without departing from the scope of the present invention, which is intended to be limited solely by the appended claims.

What is claimed is:

1. A method for shortening a temperature recovery time of a low temperature ion implantation, comprising:
implanting a wafer in a vacuum environment inside of an ion implanter, wherein a temperature of said wafer is lower than a temperature of an external environment outside of said ion implanter;
heating said wafer after said implanting process is finished; and
moving said wafer out from said ion implanter after said wafer is heated.

2. The method as set forth in claim 1, said heating process being performed at least at a specific portion of said ion implanter, wherein said specific portion comprises one or more of:
a loadlock, said loadlock being an interface between said vacuum environment and said external environment;
an implantation chamber in which said wafer is implanted; and
a robot chamber positioned to facilitate transfer of said wafer between said loadlock and said implantation chamber.

3. The method as set forth in claim 1, said heating process being performed by a specific mechanism, wherein said specific mechanism comprises one or more of:
a gas assembly, wherein a temperature of said gas is higher than a temperature of said wafer during said implanting process;
a heater, wherein said heater is embedded in a holder for holding said wafer;
a liquid assembly, wherein a temperature of liquid of said liquid assembly is higher than a temperature of said wafer during said implanting process; and
a light assembly, wherein said light assembly is capable of projecting light onto said wafer.

4. The method as set forth in claim 3, wherein said gas comprises one or more of nitrogen, hot-dry nitrogen, warm nitrogen, hot nitrogen, inert gas and a gas without vapor.

5. The method as set forth in claim 3, wherein said heater is embedded in a chuck for holding said wafer during said implanting process, such that said wafer is heated immediately after said implanting process is finished.

6. The method as set forth in claim 3, wherein said heater is embedded in a robot for transferring said wafer inside of said ion implanter, such that said wafer is heated and implanted in different portions of said ion implanter.

7. The method as set forth in claim 3, when said heating process is achieved by said liquid, said liquid only directly heating said holder for holding said wafer but not directly contacting said wafer.

8. The method as set forth in claim 3, said gas being also used to vacuum vent, such that said wafer is heated during a vacuum venting process.

9. The method as set forth in claim 8, wherein a temperature of said gas is higher than a wafer temperature during said implanting process, such that a temperature of said wafer is rapidly raised and then essentially no moisture is formed on a surface of said wafer.

10. The method as set forth in claim 3, wherein said light assembly is located outside of said ion implanter, such that said light is projected into said ion implanter and then onto said wafer.

11. The method as set forth in claim 1, said wafer being heated to a specific temperature during said heating process, wherein said specific temperature comprises one or more of:
a room temperature;
a temperature of said external environment;
a temperature higher than a freeze point of a water;
a temperature higher than a dew point of a water of said external environment; and
a temperature higher than a wafer temperature during said implanting process.

12. A method for shortening a temperature recovery time of a low temperature ion implantation, comprising:
implanting a wafer in an implantation chamber of an ion implanter;
moving said wafer to a loadlock, which is used as an interface between a vacuum environment inside of said ion implanter and an external environment outside of said ion implanter;
heating said wafer in said loadlock; and
moving said wafer out from said ion implanter after said wafer is heated.

13. The method as set forth in claim 12, said wafer being heated in a said loadlock for moving of said wafer only out from said ion implanter but not being heated in said loadlock for moving of said wafer only into said ion implanter.

14. The method as set forth in claim 12, whereby, when said wafer is held by a hot chuck in said loadlock, said wafer is heated by one or more of the following:
a heater embedded inside of said hot chuck, said heater being capable of applying heat through said hot chuck into said wafer;
a liquid flowing through said hot chuck, wherein said liquid does not directly contact said wafer and a temperature of said liquid is higher than a wafer temperature during said implanting process;
a light assembly, wherein said light assembly is capable of projecting light onto said wafer; and
a gas flowing through said wafer, wherein a temperature of said gas is higher than a wafer temperature during said implanting process.

15. The method as set forth in claim 14, wherein said gas flows through said wafer during a vacuum venting process.

16. The method as set forth in claim 12, said wafer being heated to a specific temperature during said heating process, wherein said specific temperature comprises one or more of:
a room temperature;
a temperature of an external environment where said wafer is moved into from said ion implanter;
a temperature higher than a freeze point of a water;
a temperature higher than a dew point of a water of an external environment where said wafer is moved into from said ion implanter; and
a temperature higher than a wafer temperature during said implanting process.

17. An ion implanter capable of shortening a temperature recovery time of a low temperature ion implantation, comprising:
at least a loadlock, said loadlock being an interface between an external environment outside of said ion implanter and an internal vacuum environment inside of said ion implanter;
an implantation chamber where a low temperature ion implantation is performed;
a robot capable of transferring a wafer between said loadlock and said implantation chamber; and
a heating mechanism capable of heating said wafer inside of said ion implanter.

18. The ion implanter as set forth in claim 17, wherein said heating mechanism is located at one or more of said loadlock, said robot, and said implantation chamber, and said heating mechanism comprises one or more of:
a gas, wherein a temperature of said gas is higher than a temperature of said wafer during said implanting process, wherein said gas directly contacts said wafer;
a heater, said heater being embedded in a holder for holding said wafer;
a liquid, wherein a temperature of said liquid is higher than a temperature of said wafer during said implanting process, wherein said liquid directly heats said holder for holding said wafer but does not directly contact said wafer; and
a light assembly, wherein said light assembly is capable of projecting light onto said wafer.

19. The ion implanter as set forth in claim 17, wherein said gas is applied on said wafer during a vacuum venting process.

20. The method as set forth in claim 19, and further comprising a plurality of said loadlocks, with one portion of said loadlocks for moving said wafer only out from said ion implanter being capable of heating said wafer, and with another portion of said loadlocks for moving said wafer only into said ion implanter not being capable of heating said wafer.
